(19) United States
(12) Patent Application Publication
(10) Pub. No.: US 2026/0173728 A1
(43) Pub. Date: Jun. 18, 2026

(54) DISPLAY PANEL AND DISPLAY DEVICE

(71) Applicants: HEFEI VISIONOX TECHNOLOGY CO., LTD., Hefei (CN); HEFEI VISIONOX ELECTRONICS CO., LTD., Hefei (CN); VISIONOX TECHNOLOGY INC., Jiangsu (CN)

(72) Inventors: Zhiwei ZHOU, Hefei (CN); Tian WANG, Hefei (CN); Jinfang ZHANG, Hefei (CN); Yang YANG, Hefei (CN); Lu ZHANG, Hefei (CN)

(73) Assignees: HEFEI VISIONOX TECHNOLOGY CO., LTD., Hefei (CN); HEFEI VISIONOX ELECTRONICS CO., LTD., Hefei (CN); VISIONOX TECHNOLOGY INC., Jiangsu (CN)

(21) Appl. No.: 19/412,050

(22) Filed: Dec. 8, 2025

Related U.S. Application Data
(63) Continuation of application No. PCT/CN2025/128672, filed on Oct. 20, 2025.

(30) Foreign Application Priority Data
Dec. 13, 2024 (CN) 202411847096.5

(51) Int. Cl. H10K 59/80; H10K 59/124; H10K 59/131; H10K 59/40; H10K 102/00

(52) U.S. Cl. CPC H10K 59/873; H10K 59/124; H10K 59/131; H10K 59/40; H10K 59/8723; H10K 2102/351

(57) ABSTRACT

A display panel and a display device. The display panel includes: a baseplate; an isolation structure disposed on one side of the baseplate, the isolation structure enclosing an isolation opening; a light-emitting layer including a light-emitting unit located in the isolation opening; an encapsulation layer including a plurality of encapsulation portions located on a side of the light-emitting unit away from the baseplate, the encapsulation portions respectively covering light-emitting units; a touch control layer located on a side of the encapsulation layer away from the baseplate, the touch control layer including a touch electrode, the touch electrode being located on the side of the encapsulation layer away from the baseplate, the touch electrode including a touch line, wherein an orthographic projection of the encapsulation portion on the baseplate and an orthographic projection of the touch line on the baseplate at least partially overlap.

### CROSS-REFERENCE TO RELATED APPLICATION

The present application is a continuation of International Application No. PCT/CN 2025/128672 filed on Oct. 20, 2025, which claims priority to Chinese Patent Application No. 202411847096.5 filed on Dec. 13, 2024, and titled “DISPLAY PANEL AND DISPLAY DEVICE”, both of which are incorporated herein by reference in their entireties.

### TECHNICAL FIELD

The present application relates to the technology field of display, and in particular, to a display panel and a display device.

### BACKGROUND

Flat-panel display devices based on technologies such as Organic Light Emitting Diode (OLED) and Light Emitting Diode (LED) are widely used in various consumer electronic products such as mobile phones, televisions, laptop computers, and desktop computers due to their advantages of high image quality, low power consumption, thin profile, and wide application range, and have become mainstream in display devices.

However, the performance of the current OLED display product needs improvement.

### SUMMARY

Embodiments of the present application provide a display panel and a display device, aiming to improve the performance of the OLED display product.

An embodiment of the first aspect of the present application provides a display panel, including: a baseplate; an isolation structure disposed on a side of the baseplate, the isolation structure enclosing an isolation opening; a light-emitting layer including a light-emitting unit located in the isolation opening; an encapsulation layer including a plurality of encapsulation portions located on a side of the light-emitting unit away from the baseplate, the encapsulation portions respectively covering light-emitting units; and a touch control layer located on a side of the encapsulation layer away from the baseplate, the touch control layer including a touch electrode, the touch electrode being located on the side of the encapsulation layer away from the baseplate, the touch electrode including a touch line, here, an orthographic projection of the encapsulation portion on the baseplate and an orthographic projection of the touch line on the baseplate at least partially overlap.

An embodiment of the second aspect of the present application provides a display device, including the display panel according to any of the foregoing embodiments.

According to the embodiments of the present application, the display panel includes the baseplate, the isolation structure, the light-emitting layer, the encapsulation layer, and the touch control layer. The isolation structure encloses the isolation opening, and the light-emitting unit is located within the isolation opening, enabling the isolation structure to mitigate the issue of crosstalk between light emitted from different light-emitting units. The encapsulation portion is configured to provide encapsulation protection for the light-emitting unit to improve the yield of the light-emitting unit. The touch control layer is located on the encapsulation layer, so as to mitigate the impact of the touch control layer on the encapsulation effect of the encapsulation layer. The touch electrode of the touch control layer is used to implement the touch function of the display panel. The surface of the encapsulation portion away from the baseplate is uneven, which may affect the display effect of the display panel. The orthographic projection of the encapsulation portion on the baseplate and the orthographic projection of the touch line on the baseplate at least partially overlap, allowing the touch line to cover at least a part of the encapsulation portion, which can improve the display effect of the display panel and enhance the performance of the display panel.

### BRIEF DESCRIPTION OF THE DRAWINGS

Other features, objectives, and advantages of the present application will become more apparent upon reading the following detailed description of non-limiting embodiments with reference to the accompanying drawings, here, the same or similar reference numerals represent the same or similar features, and the drawings are not necessarily drawn to scale.

FIG. 1 is a schematic structural diagram of a display panel according to an embodiment of the present application;

FIG. 2 is a cross-sectional view at A-A in FIG. 1;

FIG. 3 is a cross-sectional view at B-B in FIG. 1;

FIG. 4 is a partially enlarged schematic structural diagram of region I in FIG. 2;

FIG. 5 is a schematic structural diagram of a display panel according to another embodiment of the present application;

FIG. 6 is a cross-sectional view at C-C in FIG. 5;

FIG. 7 is a schematic structural diagram of a display panel according to another embodiment of the present application;

FIG. 8 is a schematic structural diagram of a display panel according to another embodiment of the present application;

FIG. 9 is a cross-sectional view at D-D in FIG. 8;

FIG. 10 is a partial cross-sectional view of a display panel according to an embodiment of the present application;

FIG. 11 is a schematic structural diagram of a display panel according to another embodiment of the present application;

FIG. 12 is a cross-sectional view at E-E in FIG. 11;

FIG. 13 is a schematic structural diagram of a display panel according to another embodiment of the present application;

FIG. 14 is a schematic structural diagram of a display panel according to another embodiment of the present application.

### DESCRIPTION OF REFERENCE NUMERALS

100: baseplate; 110: substrate; 120: transistor; 130: first insulating layer; 131: connection via;
200: isolation structure; 201: first sub-layer; 202: second sub-layer; 203: third sub-layer; 210: isolation opening; 220: first isolation segment; 230: second isolation segment;
300: light-emitting layer; 310: light-emitting unit; 311: first light-emitting unit; 312: second light-emitting unit; 313: third light-emitting unit; 320: pixel definition layer; 321: pixel defining portion; 322: pixel opening;
400: encapsulation layer; 401: first encapsulation layer; 402: second encapsulation layer; 403: third encapsulation layer; 410: encapsulation portion; 410a: overlapping portion; 411: first encapsulation portion; 412: second encapsulation portion; 413: third encapsulation portion; 420: first segment; 421: first main body portion; 430: second segment; 431: second main body portion; 432: first sidewall; 433: third main body portion; 440: continuous region;
500: touch control layer; 501: first touch electrode; 501a: first touch portion; 501b: first connection portion; 502: second touch electrode; 502a: second touch portion; 502b: second connection portion; 503: dummy electrode; 510: touch electrode; 511: touch line; 511a: first touch segment; 511b: second touch segment; 512: first wiring portion; 513: second wiring portion; 513a: first sub-wiring; 513b: second sub-wiring; K: hollowed region; K1: first hollowed portion; K2: second hollowed portion; 520: first touch layer; 521: first touch segment;
530: second touch layer; 531: second touch segment; 540: insulating dielectric layer; 541: dielectric via; 550: gap;
600: first electrode layer; 610: first electrode;
700: second electrode; 710: redundant unit;
Q1: first gap; Q2: second gap; Q3: third gap; Q4: fourth gap; Y: first direction; X: second direction; L1: first pixel column; L2: second pixel column; L3: third pixel column; S1: virtual quadrilateral.

### Detailed Description

Features and exemplary embodiments of various aspects of the present application will be described in detail below. To make the objectives, technical solutions, and advantages of the present application more clear, the present application will be further described in detail below with reference to the accompanying drawings and specific embodiments. It should be understood that the specific embodiments described herein are merely configured to explain the present application and are not configured to limit the present application. For those skilled in the art, the present application can be implemented without some of these specific details. The description of the embodiments below is merely to provide a better understanding of the present application by illustrating examples of the present application.

It should be understood that when describing the structure of a component, if one layer or region is referred to as being “on” or “above” another layer or region, it may mean being directly on the other layer or region, or there may be an intervening layer or region between them. Moreover, if the component is flipped, the one layer or region will be “under” or “below” the other layer or region.

The embodiments of the present application provide a display panel, a display device, and a manufacturing method for the display panel. Various embodiments of the display panel, the display device, and the manufacturing method will be described below with reference to the accompanying drawings.

An embodiment of the present application provides a display panel. The display panel may be an Organic Light Emitting Diode (OLED) display panel.

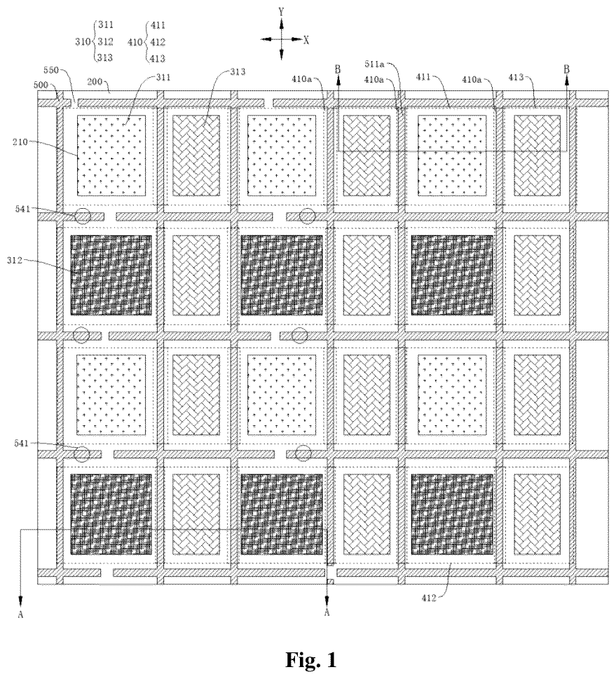

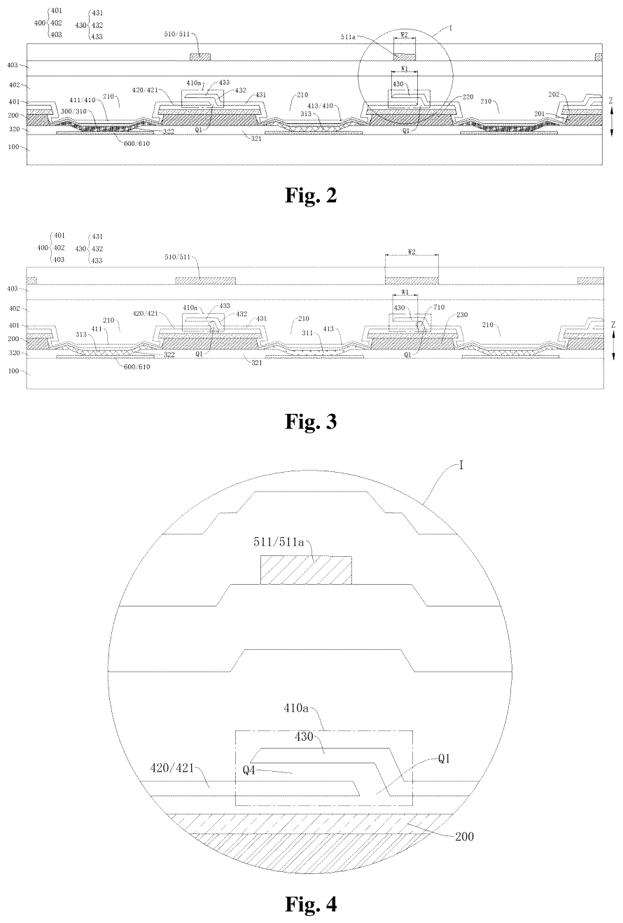

Please refer collectively to FIG. 1 to FIG. 3. FIG. 1 is a partial cross-sectional view of a display panel according to an embodiment of the present application; FIG. 2 is a cross-sectional view at A-A in FIG. 1 in an example; FIG. 3 is a cross-sectional view at B-B in FIG. 1 in an example.

As shown in FIG. 1 to FIG. 3, a first aspect of the embodiments of the present application provides a display panel. The display panel includes: a baseplate 100; an isolation structure 200 disposed on a side of the baseplate 100, the isolation structure 200 enclosing an isolation opening 210; a light-emitting layer 300 including a light-emitting unit 310 located in the isolation opening 210; an encapsulation layer 400 including a plurality of encapsulation portions 410 located on a side of the light-emitting unit 310 away from the baseplate 100, the encapsulation portions 410 respectively covering light-emitting units 310; and a touch control layer 500 located on a side of the encapsulation layer 400 away from the baseplate 100, the touch control layer 500 including a touch electrode 510, the touch electrode 510 being located on the side of the encapsulation layer 400 away from the baseplate 100, the touch electrode 510 including a touch line 511, here, an orthographic projection of the encapsulation portion 410 on the baseplate 100 and an orthographic projection of the touch line 511 on the baseplate 100 at least partially overlap.

According to the display panel of the embodiment of the present application, the display panel includes the baseplate 100, the isolation structure 200, the light-emitting layer 300, the encapsulation layer 400, and the touch control layer 500. The isolation structure 200 encloses the isolation opening 210, and the light-emitting unit 310 is located within the isolation opening 210, enabling the isolation structure 200 to mitigate the issue of crosstalk between different light-emitting units 310. The encapsulation portion 410 is configured to provide encapsulation protection for the light-emitting unit 310 to improve the yield of the light-emitting unit. The touch control layer 500 is located on the encapsulation layer 400, so as to mitigate the impact of the touch control layer 500 on the encapsulation effect of the encapsulation layer 400. The touch electrode 510 of the touch control layer 500 is used to implement the touch function of the display panel. The surface of the encapsulation portion 410 away from the baseplate 100 is uneven, which may affect the display effect of the display panel. The orthographic projection of the encapsulation portion 410 on the baseplate 100 and the orthographic projection of the touch line 511 on the baseplate 100 at least partially overlap, allowing the touch line 511 to cover at least part of the encapsulation portion 410, which can improve the display effect of the display panel and enhance the performance of the display panel.

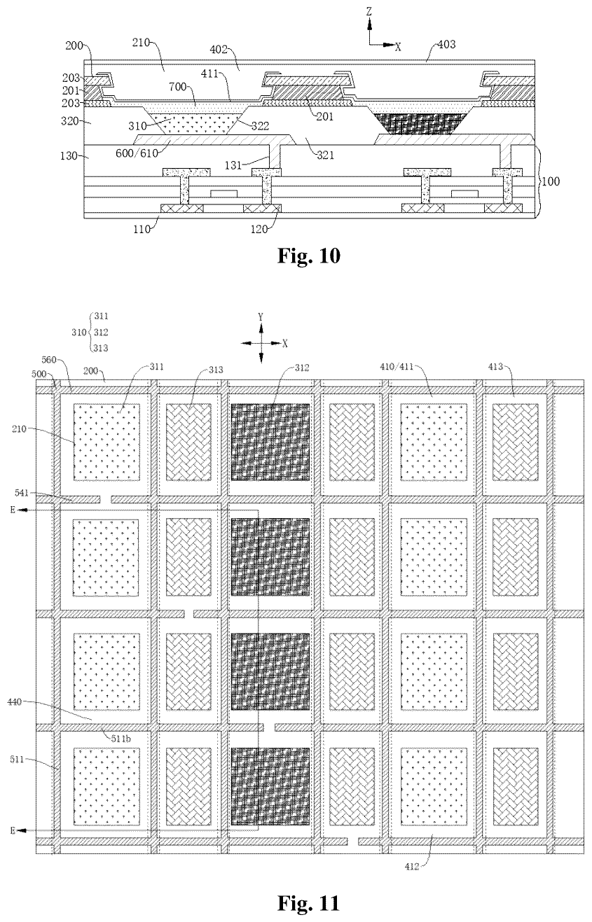

The baseplate 100 can be arranged in various ways. As shown in FIG. 10, the baseplate 100 may include a substrate 110 and a pixel circuit disposed on the substrate 110. The baseplate 100 includes a first conductive layer, a second conductive layer, and a third conductive layer. The pixel circuit may include a transistor 120 and a capacitor. The transistor 120 includes a semiconductor, a gate, a source, and a drain. The capacitor includes a first plate and a second plate. The gate and the first plate may be located in the first conductive layer, the second plate is located in the second conductive layer, and the source and the drain are located in the third conductive layer.

Optionally, as shown in FIG. 10, a first insulating layer 130 is further disposed on the baseplate 100. A first electrode layer 600 is disposed on a side of the first insulating layer 130 away from the baseplate 100. The first electrode layer 600 includes a plurality of first electrodes 610 spaced apart. Optionally, the first insulating layer 130 may be a planarization layer.

Optionally, the display panel further includes a pixel definition layer 320. The pixel definition layer 320 is located on a side of the first insulating layer 130 away from the baseplate 100. The pixel definition layer 320 includes a pixel defining portion 321 and a pixel opening 322. The first electrode 610 is exposed through the pixel opening 322. The pixel opening 322 is configured to accommodate the light-emitting unit 310.

There are various ways to arrange the relative positions of the isolation structure 200 and the pixel definition layer 320. The isolation structure 200 may be located on a side of the pixel defining portion 321 away from the baseplate 100. Alternatively, the pixel defining portion 321 may further enclose a recess opening, and the isolation structure 200 is located in the recess opening. The embodiment of the present application uses the example in which the isolation structure 200 is located on the side of the pixel defining portion 321 away from the baseplate 100 for illustration. Optionally, an orthographic projection of the pixel opening 322 on the baseplate 100 and an orthographic projection of the isolation opening 210 on the baseplate 100 at least partially overlap. For example, the orthographic projection of the pixel opening 322 on the baseplate 100 is located within the orthographic projection of the isolation opening 210 on the baseplate 100, so that the isolation structure 200 does not affect the light emission of the light-emitting unit 310. The light-emitting unit 310 is located within the pixel opening 322 inside the isolation opening 210.

Optionally, the display panel further includes a second electrode layer. The second electrode layer includes a second electrode 700 located on a side of the light-emitting unit 310 away from the baseplate 100. The first electrode 610, the second electrode 700, and the light-emitting unit 310 form a light-emitting device. One of the first electrode 610 and the second electrode 700 is an anode, and the other is a cathode. The embodiment of the present application uses the example in which the first electrode 610 is the anode and the second electrode 700 is the cathode for illustration.

Optionally, please refer to FIG. 1, FIG. 2, and FIG. 10 collectively. The encapsulation layer 400 includes a first encapsulation layer 401, a second encapsulation layer 402, and a third encapsulation layer 403. The first encapsulation layer 401 includes a plurality of encapsulation portions 410. The second encapsulation layer 402 and the third encapsulation layer 403 may be formed as entire planes, respectively. The touch control layer 500 may be located on a side of the third encapsulation layer 403 away from the second encapsulation layer 402 to improve the encapsulation effect of the encapsulation layer 400.

There are various ways to arrange the relative positions of adjacent two encapsulation portions 410. Orthographic projections of adjacent two encapsulation portions 410 on the baseplate 100 may be spaced apart from each other. Alternatively, in some other optional embodiments, encapsulation portions 410 corresponding to at least two adjacent light-emitting units 310 overlap with each other to form an overlapping portion 410a. An orthographic projection of the overlapping portion 410a on the baseplate 100 and the orthographic projection of the touch line 511 on the baseplate 100 at least partially overlap. FIG. 2 and FIG. 3 outline the location of the overlapping portion 410a with dashed lines; the dashed lines do not constitute a structural limitation in the present application. Optionally, the overlapping portion 410a is formed by the overlap of adjacent two encapsulation portions 410. The overlapping portion 410a includes the parts of the adjacent two encapsulation portions 410 that overlap with each other.

In these optional embodiments, the at least two adjacent encapsulation portions 410 overlap with each other to form the overlapping portion 410a. The surface of the overlapping portion 410a is more uneven. The orthographic projection of the overlapping portion 410a on the baseplate 100 and the orthographic projection of the touch line 511 on the baseplate 100 at least partially overlap, allowing the touch line 511 to cover at least a part of the overlapping portion 410a, thereby improving the display effect of the display panel. Furthermore, as shown in FIG. 2 and FIG. 4, since the encapsulation portions 410 overlap with each other at the overlapping portion 410a, the height of the surface of the overlapping portion 410a is higher. Arranging the touch line 511 on the overlapping portion 410a can increase the distance between the touch line 511 and other conductive layers below, mitigating parasitic issues between the touch line 511 and other conductive film layers, such as mitigating parasitic capacitance between the touch line 511 and the isolation structure 200, or between the touch line 511 and metal traces within the baseplate 100.

In some optional embodiments, as shown in FIG. 3, the orthographic projection of the overlapping portion 410a on the baseplate 100 is located within the orthographic projection of the touch line 511 on the baseplate 100, so that the touch line 511 can better cover the overlapping portion 410a and better improve the display effect of the display panel.

Under a condition that the orthographic projection of the overlapping portion 410a on the baseplate 100 is located within the orthographic projection of the touch line 511 on the baseplate 100, the width W1 of the overlapping portion 410a may be 2 μm to 5 μm, for example, the width W1 of the overlapping portion 410a may be 2 μm, 2.2 μm, 3 μm, 3.5 μm, 4.2 μm, 5 μm, etc. This addresses the issue where if the width W1 of the overlapping portion 410a is too small, it cannot properly support the touch line 511, and reduces the protective effect provided by the upper encapsulation portion 410 in the overlapping portion 410a to the lower encapsulation portion 410 during the manufacturing process, leading to reduced encapsulation reliability. Furthermore, if the width W1 of the overlapping portion 410a is too large, it may cause the overlapping portion 410a to be prone to breakage, and also affect the coverage of the overlapping portion 410a by the touch line 511. And/or, the width W2 of the touch line 511 is 3 μm to 6 μm, for example, the width W2 of the touch line 511 is 3 μm, 3.6 μm, 4.2 μm, 4.5 μm, 5.1 μm, 6 μm, etc. This addresses the issue where if the width W2 of the touch line 511 is too small, it affects the transmission of touch signals, and also addresses the issue where if the width W2 is too large, it affects light emission.

The width direction of the overlapping portion 410a may be a direction along which the adjacent two encapsulation portions 410 forming the overlapping portion 410a are spaced apart, i.e., an arrangement direction of the two light-emitting units 310 corresponding to the adjacent two encapsulation portions 410 forming the overlapping portion 410a. In the overlapping portion 410a and the touch line 511 that are mutually overlapped, the width direction of the overlapping portion 410a is the same as the width direction of the touch line 511.

In other optional embodiments, as shown in FIG. 2, the touch line 511 includes a first touch segment 511a. The orthographic projection of the first touch segment 511a on the baseplate 100 is located within the orthographic projection of the overlapping portion 410a on the baseplate 100. The first touch segment 511a is a segment of the touch line 511 that overlaps with the overlapping portion 410a. That is, the width of the first touch segment 511a is less than the width of the overlapping portion 410a, so that the orthographic projection of the first touch segment 511a on the baseplate 100 is located within the orthographic projection of the overlapping portion 410a on the baseplate 100. This allows the overlapping portion 410a to provide better support for the first touch segment 511a, and better mitigates the parasitic capacitance issue between the first touch segment 511a and the metal wirings on a side of the baseplate 100.

Optionally, the width W2 of the touch line 511 is 3 μm to 6 μm, for example, the width W2 of the touch line 511 is 3 μm, 3.6 μm, 4.2 μm, 4.5 μm, 5.1 μm, 6 μm, etc. This addresses the issue where if the width W2 of the touch line 511 is too small, it affects the transmission of touch signals, and also addresses the issue where if the width W2 is too large, it affects light emission. Under a condition that the width W2 of the touch line 511 is within a suitable range, it can also ensure that the orthographic projection of the first touch segment 511a on the baseplate 100 is located within the orthographic projection of the overlapping portion 410a on the baseplate 100.

Optionally, under a condition that the width of the first touch segment 511a is less than the width of the overlapping portion 410a, the distance from the first touch segment 511a to the isolation openings 210 on both sides of the first touch segment 511a in the width direction is greater than the distance from the overlapping portion 410a to the isolation openings 210 on both sides of the overlapping portion 410a. The distance between the first touch segment 511a and the isolation opening 210 is a minimum spacing between the orthographic projection of the first touch segment 511a on the baseplate 100 and the orthographic projection of the isolation opening 210 on the baseplate 100. The distance between the overlapping portion 410a and the isolation opening 210 is a minimum spacing between the orthographic projection of the overlapping portion 410a on the baseplate 100 and the orthographic projection of the isolation opening 210 on the baseplate 100.

In some optional embodiments, as shown in FIG. 2, the encapsulation portion 410 extends from the isolation opening 210 to a side of the isolation structure 200 away from the baseplate 100, that is, the encapsulation portion 410 covers a part of the isolation structure 200, so as to increase the distribution area of the encapsulation portion 410 and improve the encapsulation effect.

Optionally, the overlapping portion 410a is located on the side of the isolation structure 200 away from the baseplate 100. The orthographic projection of the touch line 511 on the baseplate 100 and the orthographic projection of the isolation structure 200 on the baseplate 100 at least partially overlap.

In these optional embodiments, the overlapping portion 410a is located on the side of the isolation structure 200 away from the baseplate 100, that is, the adjacent two encapsulation portions 410 overlap on the isolation structure 200. Furthermore, the orthographic projection of the touch line 511 on the baseplate 100 and the orthographic projection of the isolation structure 200 on the baseplate 100 at least partially overlap. The touch line 511 being located on the isolation structure 200 can mitigate the impact of the touch line 511 on the light emission of the light-emitting unit 310 within the isolation opening 210. Moreover, both the touch line 511 and the overlapping portion 410a are located on the isolation structure 200, allowing the touch line 511 and the overlapping portion 410a to overlap with each other.

In some optional embodiments, as shown in FIG. 2 and FIG. 3, in adjacent two encapsulation portions 410, one includes a first segment 420 located on the side of the isolation structure 200 away from the baseplate 100, and the other includes a second segment 430 located on the side of the isolation structure 200 away from the baseplate 100. The first segment 420 includes a first main body portion 421. The second segment 430 includes a second main body portion 431, a first sidewall 432, and a third main body portion 433. Here, the second main body portion 431 is connected to the third main body portion 433 through the first sidewall 432. The third main body portion 433 is located on a side of the first main body portion 421 away from the baseplate 100. The third main body portion 433 and the first main body portion 421 overlap to form the overlapping portion 410a. The overlapping portion 410a includes a part of the first main body portion 421 overlapping with the third main body portion 433 and a part of the third main body portion 433 overlapping with the first main body portion.

In these optional embodiments, the third main body portion 433 of the second segment 430 extends to the side of the first main body portion 421 away from the baseplate 100 via the first sidewall 432, causing the first main body portion 421 of the first segment 420 and the third main body portion 433 of the second segment 430 to overlap and form the overlapping portion 410a.

Optionally, as shown in FIG. 4, a fourth gap Q4 is formed between the first main body portion 421 and the third main body portion 433. During the manufacturing process of the light-emitting unit 310 covered by the second segment 430, portions of the light-emitting material, the electrode material, and the encapsulation material are sequentially stacked and cover the first main body portion 421. During subsequent patterning of the light-emitting material, the electrode material, and the encapsulation material, the light-emitting material and the electrode material between the third main body portion 433 and the first main body portion 421 are removed to form the aforementioned fourth gap Q4.

Optionally, the fourth gap Q4 is filled with an organic filling portion. When manufacturing the second encapsulation layer 402 after the first encapsulation layer 401 is manufactured, a part of the material of the second encapsulation layer 402 may flow into the fourth gap Q4 to form the organic filling portion. The organic filling portion can provide support for the third main body portion 433, ensuring the positional stability between the first main body portion 421 and the third main body portion 433, and also improving the yield of the third main body portion 433.

Optionally, the thickness of the organic filling portion is less than the thickness of the first main body portion 421 or the third main body portion 433. The thickness of the organic filling portion is relatively small, that is, the distance between the first main body portion 421 and the third main body portion 433 is relatively small, which ensures sealing performance and the stability of the relative positions between the first main body portion 421 and the third main body portion 433.

In some optional embodiments, under a condition that the encapsulation portion 410 includes the first main body portion 421, the second main body portion 431, the first sidewall 432, and the third main body portion 433, a first gap Q1 is formed between the first main body portion 421 and the first sidewall 432. The orthographic projection of the first gap Q1 on the baseplate 100 and the orthographic projection of the touch line 511 on the baseplate 100 at least partially overlap. Residual materials that may affect the display effect might exist in the first gap Q1 during the manufacturing process. The touch line 511 covering the first gap Q1 can improve the display effect. For example, as shown in FIG. 3, a redundant unit 710 is provided on the side of the third main body portion 433 facing the isolation structure 200. At least a part of the redundant unit 710 fills the first gap Q1. The redundant unit 710 is formed from the aforementioned residual materials, and the surface of the redundant unit 710 may be uneven.

Optionally, the material of the redundant unit 710 is the same as the material of the second electrode 700. The uneven surface of the redundant unit 710 may reflect light, causing display difference in the first gap Q1. In the embodiment of the present application, the orthographic projection of the first gap Q1 on the baseplate 100 and the orthographic projection of the touch line 511 on the baseplate 100 at least partially overlap, allowing the touch line 511 to cover the first gap Q1 and mitigating the display difference at the location of the first gap Q1.

Optionally, the orthographic projection of the first gap Q1 on the baseplate 100 is located within the orthographic projection of the touch line 511 on the baseplate 100, allowing the touch line 511 to better cover the first gap Q1.

In some optional embodiments, an orthographic projection of a side edge of the third main body portion 433 away from the first sidewall 432 on the baseplate 100 is located within the orthographic projection of the touch line 511 on the baseplate 100.

In these optional embodiments, there is a height difference between the side edge of the third main body portion 433 away from the first sidewall 432 and the first main body portion 421, causing the film surface to be uneven and potentially affecting the display effect. The orthographic projection of the side edge of the third main body portion 433 away from the first sidewall 432 on the baseplate 100 is located within the orthographic projection of the touch line 511 on the baseplate 100, so that the touch line 511 can cover the side edge of the third main body portion 433 away from the first sidewall 432, thereby mitigating the impact of the height difference on the display effect, such as improving display uniformity when the screen is off.

Optionally, the orthographic projection of the third main body portion 433 on the baseplate 100 is located within the orthographic projection of the touch line 511 on the baseplate 100. During the manufacturing process of the display panel, due to the presence of the third main body portion 433, a part of the material covered by the third main body portion 433 remains between the third main body portion 433 and the first main body portion 421, resulting in a difference in reflectivity in the region where the third main body portion 433 is located. In the embodiment of the present application, the third main body portion 433 is covered by the touch line 511, allowing the touch line 511 to cover more of the encapsulation portion 410 and any possible residual material, thereby better improving the display effect.

Optionally, the orthographic projection of the first sidewall 432 on the baseplate 100 is located within the orthographic projection of the touch line 511 on the baseplate 100. During the manufacturing process of the display panel, due to the presence of the first sidewall 432, a part of the material covered by the first sidewall 432 remains between the first sidewall 432 and the isolation structure 200 (such as the aforementioned redundant unit 710), resulting in a difference in reflectivity in the region where the first sidewall 432 is located. In the embodiment of the present application, the first sidewall 432 is covered by the touch line 511, allowing the touch line 511 to cover more of the encapsulation portion 410 and the residual material, thereby better improving the display effect.

An orthographic projection of a side edge of the first main body portion 421 facing the second main body portion 431 on the baseplate 100 is located within the orthographic projection of the touch line 511 on the baseplate 100. This allows the touch line 511 to cover more of the encapsulation portion 410 and also allows the touch line 511 to better cover the aforementioned redundant unit 710, thereby better improving the display effect.

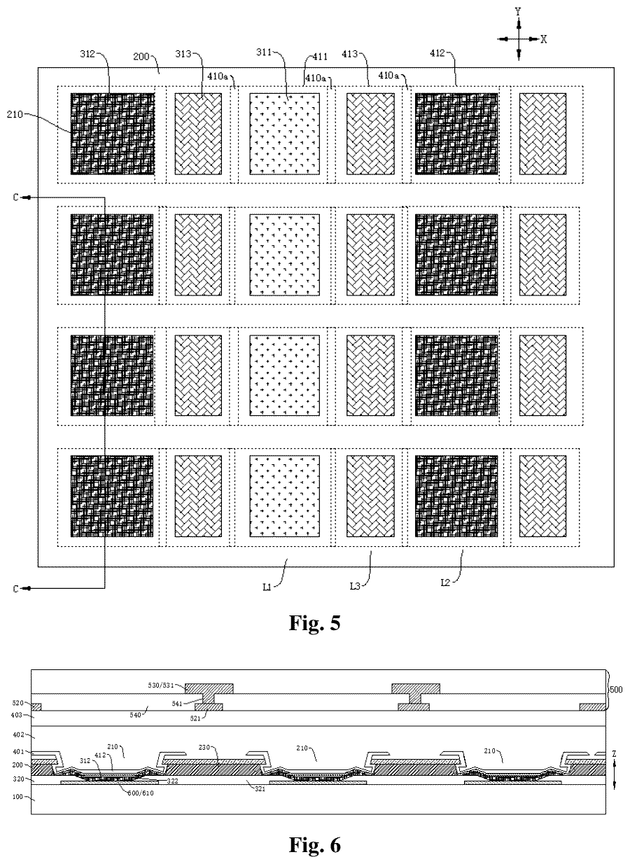

The arrangement of a plurality of light-emitting units 310 can vary. As shown in FIG. 1 and FIG. 5, in some optional embodiments, the plurality of light-emitting units 310 are arranged in rows and columns along a first direction Y and a second direction X. The first direction Y is the column direction, and the second direction X is the row direction. Adjacent two encapsulation portions 410 in the same row along the second direction X overlap with each other to form the overlapping portion 410a.

In these optional embodiments, adjacent two encapsulation portions 410 in the same row overlap with each other to form the overlapping portion 410a, improving the encapsulation effect of the encapsulation layer 400.

Optionally, orthographic projections of adjacent two encapsulation portions 410 in the same column along the first direction Y on the baseplate 100 are spaced apart from each other. This simplifies the structure of the encapsulation portions 410 and prevents the encapsulation portion 410 above the isolation structure 200 from extending too long in the first direction Y, which could cause the overlapping portion 410a to be prone to breakage.

Optionally, as shown in FIG. 10, the first insulating layer 130 is penetrated by and provided with a connection via 131. The first electrode 610 is electrically connected to the transistor 120 through the connection via 131. Under a condition that the plurality of light-emitting units 310 are arranged in rows and columns, the distance between adjacent two light-emitting units 310 in the row direction is usually smaller, and the distance between adjacent two light-emitting units 310 in the column direction is larger, allowing structures like the connection via 131 to be arranged between adjacent two light-emitting units 310 in the column direction. Therefore, by arranging adjacent two encapsulation portions 410 in the same row to overlap with each other, the two encapsulation portions 410 that are relatively close can overlap with each other to form the overlapping portion 410a; by arranging adjacent two encapsulation portions 410 in the same column to be spaced apart, the orthographic projections of the two encapsulation portions 410 that are relatively far away on the baseplate 100 are spaced apart, which can improve the encapsulation reliability of the encapsulation portions 410 and prevent the encapsulation portion 410 above the isolation structure 200 from breaking.

Optionally, the plurality of light-emitting units 310 include a first light-emitting unit 311, a second light-emitting unit 312, and a third light-emitting unit 313. The first light-emitting unit 311, the second light-emitting unit 312, and the third light-emitting unit 313 are configured to emit light of different colors. The first light-emitting unit 311 may be configured to emit red light, the second light-emitting unit 312 may be configured to emit blue light, and the third light-emitting unit 313 may be configured to emit green light. In other embodiments, the first light-emitting unit 311 may also be configured to emit blue or green light, the second light-emitting unit 312 may be configured to emit red or green light, and the third light-emitting unit 313 may be configured to emit red or blue light.

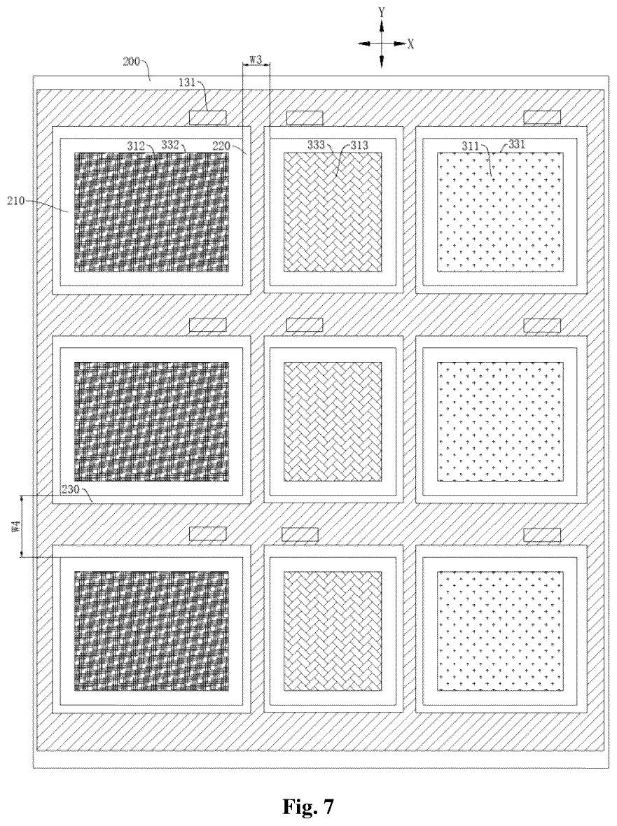

In some optional embodiments, as shown in FIG. 5 and FIG. 6, a plurality of first light-emitting units 311 are arranged sequentially along the first direction Y to form a first pixel column L1. A plurality of second light-emitting units 312 are arranged sequentially along the first direction Y to form a second pixel column L2. The first pixel column L1 and the second pixel column L2 are arranged along the second direction X. The encapsulation portions 410 include a first encapsulation portion 411 covering the first light-emitting unit 311 and a second encapsulation portion 412 covering the second light-emitting unit 312. The first encapsulation portion 411 and the second encapsulation portion 412 adjacent along the second direction X overlap with each other to form the overlapping portion 410a.

In these optional embodiments, the plurality of first light-emitting units 311 are distributed sequentially along the first direction Y, and the plurality of second light-emitting units 312 are distributed sequentially along the first direction Y, which can simplify the pixel arrangement structure. The distance between the first encapsulation portion 411 and the second encapsulation portion 412 adjacent along the second direction X is relatively small, and the first encapsulation portion 411 and the second encapsulation portion 412 adjacent along the second direction X overlap to form the overlapping portion 410a, which can improve the encapsulation reliability of the encapsulation portions 410.

Optionally, orthographic projections of adjacent two first encapsulation portions 411 along the first direction Y on the baseplate 100 are spaced apart from each other. The distance between the first encapsulation portions 411 corresponding to adjacent two first light-emitting units 311 in the first pixel column L1 is relatively large. Therefore, by arranging the orthographic projections of the adjacent two first encapsulation portions 411 along the first direction Y on the baseplate 100 to be spaced apart, the encapsulation reliability of the encapsulation portions 410 can be improved and the structure of the encapsulation portions 410 can be simplified.

And/or, orthographic projections of adjacent two second encapsulation portions 412 along the first direction Y on the baseplate 100 are spaced apart from each other. The distance between the second encapsulation portions 412 corresponding to adjacent two second light-emitting units 312 in the second pixel column L2 is relatively large. Therefore, by arranging the orthographic projections of the adjacent two second encapsulation portions 412 along the first direction Y on the baseplate 100 to be spaced apart, the encapsulation reliability of the encapsulation portions 410 can be improved and the structure of the encapsulation portions 410 can be simplified.

Optionally, please refer to the above, the plurality of light-emitting units 310 further include a third light-emitting unit 313. A plurality of third light-emitting units 313 are arranged sequentially along the first direction Y to form a third pixel column L3. The first pixel column L1, the second pixel column L2, and the third pixel column L3 are alternately arranged along the second direction X. The encapsulation portions 410 further include a third encapsulation portion 413 covering the third light-emitting unit 313. The second encapsulation portion 412 and the third encapsulation portion 413 adjacent along the second direction X overlap with each other to form the overlapping portion 410a, and/or the first encapsulation portion 411 and the third encapsulation portion 413 adjacent along the second direction X overlap with each other to form the overlapping portion 410a.

In these optional embodiments, the distance between the third encapsulation portion 413 and the first encapsulation portion 411 or the second encapsulation portion 412 adjacent to the third encapsulation portion 413 along the second direction X is relatively small. Therefore, by arranging the second encapsulation portion 412 and the third encapsulation portion 413 adjacent along the second direction X to overlap with each other to form the overlapping portion 410a, and/or arranging the first encapsulation portion 411 and the third encapsulation portion 413 adjacent along the second direction X to overlap with each other to form the overlapping portion 410a, the encapsulation reliability of the encapsulation portions 410 can be improved and the structure of the encapsulation portions 410 can be simplified.

Optionally, orthographic projections of adjacent two third encapsulation portions 413 along the first direction Y on the baseplate 100 are spaced apart from each other. The distance between the third encapsulation portions 413 corresponding to adjacent two third light-emitting units 313 in the third pixel column L3 is relatively large. Therefore, by arranging the orthographic projections of adjacent two third encapsulation portions 413 along the first direction Y on the baseplate 100 to be spaced apart, the encapsulation reliability of the encapsulation portions 410 can be improved and the structure of the encapsulation portions 410 can be simplified.

In other optional embodiments, as shown in FIG. 1, the first light-emitting unit 311 and the second light-emitting unit 312 are alternately arranged along the first direction Y. The orthographic projections of the first encapsulation portion 411 and the second encapsulation portion 412 adjacent along the first direction Y on the baseplate 100 are spaced apart from each other. The first light-emitting unit 311 and the third light-emitting unit 313 are alternately arranged along the second direction X, and the first encapsulation portion 411 and the third encapsulation portion 413 adjacent along the second direction X form the overlapping portion 410a; and/or the second light-emitting unit 312 and the third light-emitting unit 313 are alternately arranged along the second direction X, and the second encapsulation portion 412 and the third encapsulation portion 413 adjacent along the second direction X form the overlapping portion 410a.

In these optional embodiments, the first light-emitting unit 311 and the second light-emitting unit 312 are alternately arranged along the first direction Y to form a same pixel column. Therefore, the distance between the first encapsulation portion 411 corresponding to the first light-emitting unit 311 and the second encapsulation portion 412 corresponding to the second light-emitting unit 312 is relatively large. By arranging the orthographic projections of the first encapsulation portion 411 and the second encapsulation portion 412 adjacent along the first direction Y on the baseplate 100 to be spaced apart, the structure of the encapsulation portions 410 can be simplified. The first light-emitting unit 311 and the third light-emitting unit 313 are alternately arranged along the second direction X to form a same pixel row. Therefore, the distance between the first encapsulation portion 411 corresponding to the first light-emitting unit 311 and the third encapsulation portion 413 corresponding to the third light-emitting unit 313 is relatively small. By arranging the first encapsulation portion 411 and the third encapsulation portion 413 adjacent along the second direction X to form the overlapping portion 410a, the structure of the encapsulation portions 410 can be simplified. Similarly, the second light-emitting unit 312 and the third light-emitting unit 313 are alternately arranged along the second direction X to form a same pixel row. Therefore, the distance between the second encapsulation portion 412 corresponding to the second light-emitting unit 312 and the third encapsulation portion 413 corresponding to the third light-emitting unit 313 is relatively small. By arranging the second encapsulation portion 412 and the third encapsulation portion 413 adjacent along the second direction X to form the overlapping portion 410a, the encapsulation reliability of the encapsulation portions 410 can be improved and the structure of the encapsulation portions 410 can be simplified.

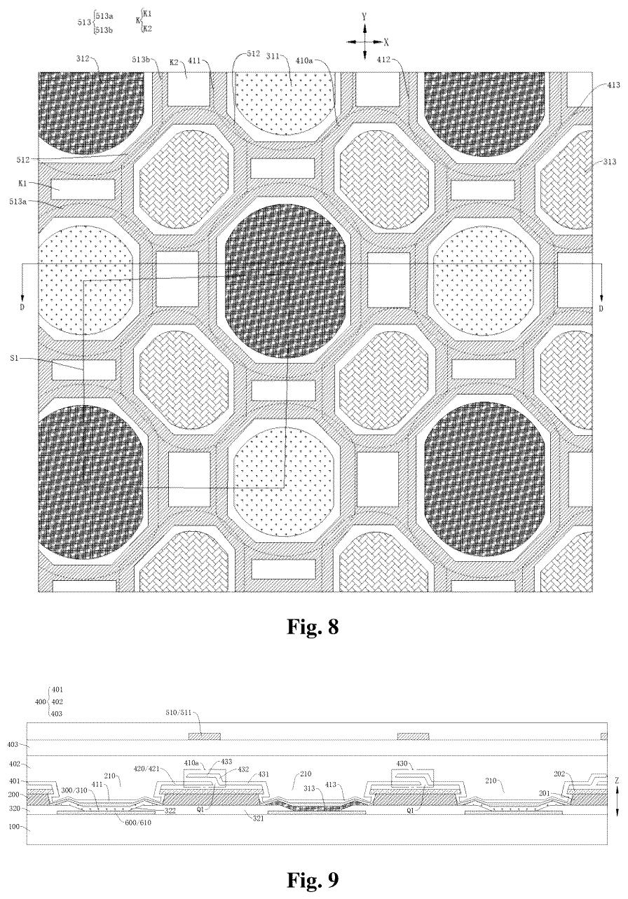

In still other optional embodiments, as shown in FIG. 8, the third light-emitting unit 313 is located within a virtual quadrilateral S1. Two first light-emitting units 311 and two second light-emitting units 312 are alternately distributed at vertices of the virtual quadrilateral S1. The first encapsulation portion 411 and the third encapsulation portion 413 adjacent along the diagonal direction of the virtual quadrilateral S1 overlap to form the overlapping portion 410a, and/or the second encapsulation portion 412 and the third encapsulation portion 413 adjacent along the diagonal direction of the virtual quadrilateral S1 overlap to form the overlapping portion 410a.

In these optional embodiments, the third light-emitting unit 313 is located within the virtual quadrilateral S1, and the first light-emitting units 311 and the second light-emitting units 312 are located at the vertices of the virtual quadrilateral S1. The distance between the first light-emitting unit 311 and the third light-emitting unit 313 is relatively small. By arranging the first encapsulation portion 411 and the third encapsulation portion 413 adjacent along the diagonal direction of the virtual quadrilateral S1 to overlap to form the overlapping portion 410a, the structure of the encapsulation portions 410 can be simplified. Similarly, the distance between the second light-emitting unit 312 and the third light-emitting unit 313 is relatively small. By arranging the second encapsulation portion 412 and the third encapsulation portion 413 adjacent along the diagonal direction of the virtual quadrilateral S1 to overlap to form the overlapping portion 410a, the encapsulation reliability of the encapsulation portions 410 can be improved and the structure of the encapsulation portions 410 can be simplified.

Optionally, the orthographic projections of the first encapsulation portion 411 and the second encapsulation portion 412 on the baseplate 100 are spaced apart. Optionally, the orthographic projections of adjacent two third encapsulation portions 413 on the baseplate 100 are spaced apart.

In some optional embodiments, as shown in FIG. 8 to FIG. 9, the touch line 511 includes a first wiring portion 512. The first wiring portion 512 is correspondingly located between the first light-emitting unit 311 and the third light-emitting unit 313 adjacent to the first light-emitting unit 311, and/or the first wiring portion 512 is correspondingly located between the second light-emitting unit 312 and the third light-emitting unit 313 adjacent to the second light-emitting unit 312. The orthographic projection of the overlapping portion 410a on the baseplate 100 and an orthographic projection of the first wiring portion 512 on the baseplate 100 at least partially overlap.

In these optional embodiments, the first wiring portion 512 is correspondingly located between the first light-emitting unit 311 and the third light-emitting unit 313 adjacent to the first light-emitting unit 311, that is, the orthographic projection of the first wiring portion 512 on the baseplate 100 is located between the orthographic projection of the first light-emitting unit 311 on the baseplate 100 and the orthographic projection of the third light-emitting unit 313 on the baseplate 100, then, the overlapping portion 410a formed by the overlap of the first encapsulation portion 411 and the third encapsulation portion 413 can overlap with the first wiring portion 512. And/or, the first wiring portion 512 is correspondingly located between the second light-emitting unit 312 and the third light-emitting unit 313 adjacent to the second light-emitting unit 312, that is, the orthographic projection of the first wiring portion 512 on the baseplate 100 is located between the orthographic projection of the second light-emitting unit 312 on the baseplate 100 and the orthographic projection of the third light-emitting unit 313 on the baseplate 100, then, the overlapping portion 410a formed by the overlap of the second encapsulation portion 412 and the third encapsulation portion 413 can overlap with the first wiring portion 512.

In some optional embodiments, the touch line 511 further includes a second wiring portion 513. The second wiring portion 513 is correspondingly located between the second light-emitting unit 312 and the first light-emitting unit 311 adjacent to the second light-emitting unit 312, and at least one second wiring portion 513 encloses a hollowed region K.

In these optional embodiments, under a condition that the first light-emitting unit 311, the second light-emitting unit 312, and the third light-emitting unit 313 are arranged in the aforementioned pixel arrangement structure, the gap between the first light-emitting unit 311 and the second light-emitting unit 312 adjacent along the first direction Y and/or the second direction X is relatively large. At least one second wiring portion 513 encloses the hollowed region K in the gap. On one hand, this makes the width of the touch line 511 in this region similar to the width of the touch line 511 in other regions, improving the wiring uniformity of the touch lines 511. On the other hand, it makes the distance from the second wiring portion 513 to the isolation opening 210 or the pixel opening 322 similar to the distance from the touch line 511 to the isolation opening 210 or the pixel opening 322 in other regions, making the impact of the touch lines 511 in different regions on the light emission of the light-emitting units 310 consistent and improving display uniformity.

Optionally, the first light-emitting unit 311 and the second light-emitting unit 312 are alternately arranged along the first direction Y to form a fourth pixel column. The first light-emitting unit 311 and the second light-emitting unit 312 are alternately arranged along the second direction X to form a first pixel row. The second wiring portion 513 is correspondingly located between the first light-emitting unit 311 and the second light-emitting unit 312 adjacent along the first direction Y and/or the second direction X. That is, the second wiring portion 513 is correspondingly located between the first light-emitting unit 311 and the second light-emitting unit 312 adjacent in the fourth pixel column, or the second wiring portion 513 is correspondingly located between the first light-emitting unit 311 and the second light-emitting unit 312 adjacent in the first pixel row.

Optionally, the second wiring portion 513 includes a first sub-wiring 513a and a second sub-wiring 513b. The first sub-wiring 513a is correspondingly located between the first light-emitting unit 311 and the second light-emitting unit 312 adjacent along the first direction Y. The second sub-wiring 513b is correspondingly located between the first light-emitting unit 311 and the second light-emitting unit 312 adjacent along the second direction X.

Optionally, the second sub-wiring 513b may enclose the aforementioned hollowed region K, and/or the first sub-wiring 513a may enclose the aforementioned hollowed region K. Optionally, due to the relatively large spacing between the first light-emitting unit 311 and the second light-emitting unit 312 adjacent along the second direction X, any second sub-wiring 513b encloses the aforementioned hollowed region K. Optionally, a part of the first sub-wirings 513a may enclose the aforementioned hollowed region K. Because that there are two types of gaps between the first light-emitting unit 311 and the second light-emitting unit 312 adjacent along the first direction Y, the first sub-wiring 513a in the larger gap can enclose the hollowed region K.

Optionally, the hollowed region K includes a first hollowed portion K1 enclosed by at least one first sub-wiring 513a and a second hollowed portion K2 enclosed by at least one second sub-wiring 513b, and an area of an orthographic projection of the first hollowed portion K1 on the baseplate 100 is smaller than an area of an orthographic projection of the second hollowed portion K2 on the baseplate 100. Please refer to the above, under a condition that both the first sub-wiring 513a and the second sub-wiring 513b enclose the hollowed regions K, the area of the first hollowed portion K1 enclosed by the first sub-wiring 513a is smaller to adapt to the pixel arrangement structure.

In some optional embodiments, as shown in FIG. 6, the touch control layer 500 includes a first touch layer 520 and a second touch layer 530. An insulating dielectric layer 540 is disposed between the first touch layer 520 and the second touch layer 530. The touch electrode 510 includes a first touch segment 521 located in the first touch layer 520 and a second touch segment 531 located in the second touch layer 530. The insulating dielectric layer 540 is provided with a dielectric via 541. The first touch segment 521 is electrically connected to the second touch segment 531 through the dielectric via 541. An orthographic projection of the dielectric via 541 on the baseplate 100 and the orthographic projection of the overlapping portion 410a on the baseplate 100 are spaced apart. In these optional embodiments, the dielectric via 541 and the overlapping portion 410a are spaced apart to further improve the display effect.

In the touch control layer 500, the aperture of the dielectric via 541 is relatively large. To mitigate the impact of the metal material in the dielectric via 541 on the light emission of the light-emitting unit 310, the dielectric via 541 is disposed on a wider isolation structure 200, so that the orthographic projection of the dielectric via 541 on the baseplate 100 is located within the orthographic projection of the isolation structure 200 on the baseplate 100. Meanwhile, to allow adjacent two encapsulation portions 410 to overlap and form the overlapping portion 410a on a narrower isolation structure 200, in the embodiment of the present application, the overlapping portion 410a and the dielectric via 541 are spaced apart, making the distribution of the overlapping portion 410a and the dielectric via 541 more reasonable.

Optionally, the orthographic projection of at least one dielectric via 541 on the baseplate 100 and the orthographic projection of at least one overlapping portion 410a on the baseplate 100 surround different sides of a same isolation opening 210, so as to facilitate the spaced arrangement of the dielectric via 541 and the overlapping portion 410a.

Optionally, as shown in FIG. 2, FIG. 6, and FIG. 7, the isolation structure 200 includes a first isolation segment 220 and a second isolation segment 230. The orthographic projection of the overlapping portion 410a on the baseplate 100 is located within the orthographic projection of the first isolation segment 220 on the baseplate 100. The orthographic projection of the dielectric via 541 on the baseplate 100 is located within the orthographic projection of the second isolation segment 230 on the baseplate 100. The width W3 of the first isolation segment 220 is less than the width W4 of the second isolation segment 230.

In these optional embodiments, the width W3 of the first isolation segment 220 is small, and the width W4 of the second isolation segment 230 is large. The adjacent encapsulation portions 410 easily form the overlapping portion 410a on the first isolation segment 220, while the dielectric via 541 is disposed on the second isolation segment 230, which can mitigate the impact of the dielectric via 541 on the light emission effect of the light-emitting unit 310.

Optionally, at least two adjacent encapsulation portions 410 are spaced apart on the side of the second isolation segment 230 away from the baseplate 100. This simplifies the structure of the encapsulation portions 410.

In some optional embodiments, as shown in FIG. 2, a ratio of the width W1 of the overlapping portion 410a to the width W2 of the touch line 511 is 1.5 to 0.5. For example, the ratio of the width W1 of the overlapping portion 410a to the width W2 of the touch line 511 is 1.5, 1.2, 1.0, 0.7, 0.5, etc. Under a condition that the width ratio of the overlapping portion 410a and the touch line 511 is within a suitable range, it can mitigate the issue where if the width of the overlapping portion 410a is too large and extends onto the light-emitting unit 310, it affects the light emission effect of the light-emitting unit 310, and also mitigate the issue where if the width of the touch line 511 is too large, it affects the light emission effect of the light-emitting unit 310. It can also mitigate the issue where if the width of the overlapping portion 410a is too small, it affects the support for the touch line 511, and also mitigate the issue where if the width of the touch line 511 is too small, it affects the transmission of touch signals.

Optionally, the orthographic projection of the overlapping portion 410a on the baseplate 100 is located within the orthographic projection of the touch line 511 on the baseplate 100. The width of the overlapping portion 410a is 2 μm to 5 μm; for example, the width W1 of the overlapping portion 410a is 2 μm, 2.2 μm, 3 μm, 3.5 μm, 4.2 μm, 5 μm, etc. This addresses the issue where if the width W1 of the overlapping portion 410a is too small, it cannot properly support the touch line 511, and also addresses the issue where if the width W1 of the overlapping portion 410a is too large, it affects the coverage by the touch line 511. And/or, the width W2 of the touch line 511 is 3 μm to 6 μm, for example, the width W2 of the touch line 511 is 3 μm, 3.6 μm, 4.2 μm, 4.5 μm, 5.1 μm, 6 μm, etc. This addresses the issue where if the width of the touch line 511 is too small, it affects the transmission of touch signals, and also addresses the issue where if the width is too large, it affects light emission.

In some optional embodiments, please refer to the above, as shown in FIG. 10, the display panel further includes a transistor 120, a first insulating layer 130, and a first electrode 610. The orthographic projection of the connection via 131 on the baseplate 100 and the orthographic projection of the overlapping portion 410a on the baseplate 100 are spaced apart.

In these optional embodiments, due to the presence of the connection via 131, a part of the pixel defining portion 321 and/or the isolation structure 200 may recess toward the baseplate 100, causing an uneven surface. The surface of the overlapping portion 410a away from the baseplate 100 is also uneven. Spacing the connection via 131 and the overlapping portion 410a apart can mitigate the accumulation of unevenness on the overlapping portion 410a, which affects the display effect of the display panel.

Optionally, the orthographic projection of the connection via 131 on the baseplate 100 and the orthographic projection of the encapsulation portion 410 on the baseplate 100 are spaced apart. This, in turn, spaces the recess formed on the isolation structure 200 due to the connection via 131 apart from the encapsulation portion 410, allowing the encapsulation portion 410 to extend along a relatively flat surface, which can improve the encapsulation effect.

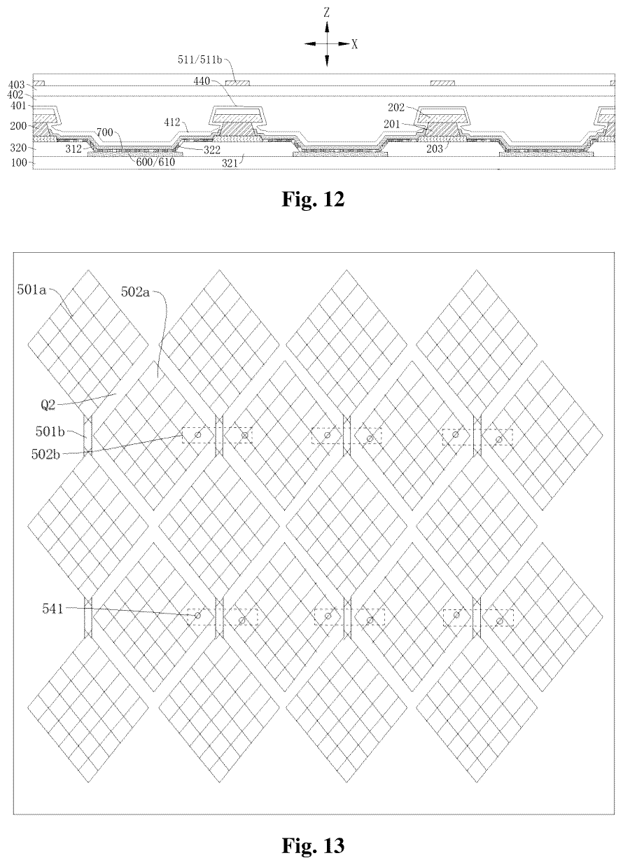

In still other optional embodiments, as shown in FIG. 11 and FIG. 12, at least two adjacent encapsulation portions 410 continuously form a continuous region 440 on the side of the isolation structure 200 away from the baseplate 100. This can simplify the structure of the encapsulation portions 410, improve the yield of the encapsulation portions 410, and thus enhance the performance of the display panel.

Optionally, the touch line 511 includes a plurality of second touch segments 511b distributed along an extending direction of the touch line 511. An orthographic projection of at least one second touch segment 511b on the baseplate 100 is located within an orthographic projection of the continuous region 440 on the baseplate 100. Optionally, the film layer height of the continuous region 440 is relatively higher compared to other regions of the first encapsulation layer 401. Arranging the second touch segment 511b on the continuous region 440 can increase the distance between the second touch segment 511b and other conductive layers below, mitigating parasitic issues between the second touch segment 511b and other conductive film layers. Furthermore, since the continuous region 440 is formed on the side of the isolation structure 200 away from the baseplate 100, at least a part of the touch line 511 correspondingly located on the isolation structure 200 is also conveniently disposed on the continuous region 440. The second touch segment 511b is the part of the touch line 511 that overlaps with the continuous region 440.

Optionally, encapsulation portions 410 corresponding to adjacent light-emitting units 310 of a same light-emitting color may form the continuous region 440. A plurality of light-emitting units 310 of the same color can be formed in the same process step. The encapsulation portions 410 corresponding to the plurality of light-emitting units 310 of the same color can be formed in the same process step. When forming the encapsulation portions 410 corresponding to the plurality of light-emitting units 310 of the same color, a part of the material can be retained, causing the encapsulation portions 410 corresponding to at least two light-emitting units 310 of the same color to be connected. This simplifies the process steps and also simplifies the structure of the first encapsulation layer 401, improves the yield of the first encapsulation layer 401, and thus enhances the performance of the display panel.

Under a condition that the encapsulation portions 410 form the continuous region 440 on the side of the isolation structure 200 away from the baseplate 100, it can be considered that the two encapsulation portions 410 forming the continuous region 440 are integrally formed. There is neither a gap nor overlap between the two encapsulation portions 410.

The isolation structure 200 can be arranged in various ways. In some optional embodiments, the isolation structure 200 includes a first sub-layer 201 and a second sub-layer 202 stacked in a direction away from the baseplate 100. The orthographic projection of the first sub-layer 201 on the baseplate 100 is located within the orthographic projection of the second sub-layer 202 on the baseplate 100.

In these optional embodiments, the second sub-layer 202 is located on the side of the first sub-layer 201 away from the baseplate 100, and the size of the second sub-layer 202 is larger than the size of the first sub-layer 201, causing a recess to be formed under the second sub-layer 202. When manufacturing the light-emitting unit 310, the light-emitting material can break at the edge of the second sub-layer 202 to form independent light-emitting units 310, eliminating the need for a precise evaporation mask to manufacture the light-emitting units 310 and simplifying the manufacturing process of the display panel.

Optionally, the isolation structure 200 further includes a third sub-layer 203 located on the side of the first sub-layer 201 facing the baseplate 100. The orthographic projection of the first sub-layer 201 on the baseplate 100 is located within the orthographic projection of the third sub-layer 203 on the baseplate 100. By providing the third sub-layer 203, during the manufacturing process of the isolation structure 200, when side-etching the first sub-layer 201 to make the size of the first sub-layer 201 smaller than the second sub-layer 202, the third sub-layer 203 can protect the film layer on the side of the isolation structure 200 facing the baseplate 100.

Optionally, the material of the isolation structure 200 includes a conductive material, and the second electrode 700 is electrically connected to the isolation structure 200, so that the plurality of second electrodes 700 can be interconnected as a surface electrode through the isolation structure 200. Optionally, the material of the first sub-layer 201 includes a conductive material, and the second electrode 700 is electrically connected to the first sub-layer 201. Optionally, the second electrode 700 is electrically connected to the third sub-layer 203, which can increase the distribution area of the conductive material and reduce the voltage drop of the second electrode 700.

Optionally, there is a gap between the continuous region 440 and the isolation structure 200. During the manufacturing process of the light-emitting unit 310, an etching material can enter between the continuous region 440 and the isolation structure 200 to remove the redundant light-emitting material between the continuous region 440 and the isolation structure 200, forming the gap between the continuous region 440 and the isolation structure 200. Optionally, the isolation structure 200 includes a top surface away from the baseplate 100, and there is a gap between the continuous region 440 and the top surface.

Optionally, the orthographic projection of the continuous region 440 on the baseplate 100 is located within the orthographic projection of the isolation structure 200 on the baseplate 100. This allows the encapsulation portion 410 to cover the isolation structure 200, and the encapsulation portion 410 can provide encapsulation protection for the isolation structure 200.

In some optional embodiments, as shown in FIG. 1, the touch control layer 500 further includes a gap 550, adjacent two touch lines 511 are spaced apart by the gap 550, and an orthographic projection of at least one gap 550 on the baseplate 100 is located outside the orthographic projection of the overlapping portion 410a on the baseplate 100. This allows more touch lines 511 to overlap with the overlapping portion 410a.

In some optional embodiments, as shown in FIG. 13, the touch electrode 510 includes first touch electrodes 501 extending along the first direction Y and arranged along the second direction X, and second touch electrodes 502 extending along the second direction X and arranged along the first direction Y. The first touch electrode 501 includes a first touch portion 501a and a first connection portion 501b. The first connection portion 501b connects adjacent two first touch portions 501a. The second touch electrode 502 includes a second touch portion 502a and a second connection portion 502b. The second connection portion 502b connects adjacent two second touch portions 502a. A second gap Q2 exists between the first touch portion 501a and the second touch portion 502a adjacent to the first touch portion 501a. An orthographic projection of the second gap Q2 on the baseplate 100 is located outside the orthographic projection of the overlapping portion 410a on the baseplate 100. The second gap Q2 and the overlapping portion 410a are spaced apart, allowing more touch lines 511 to overlap with the overlapping portion 410a.

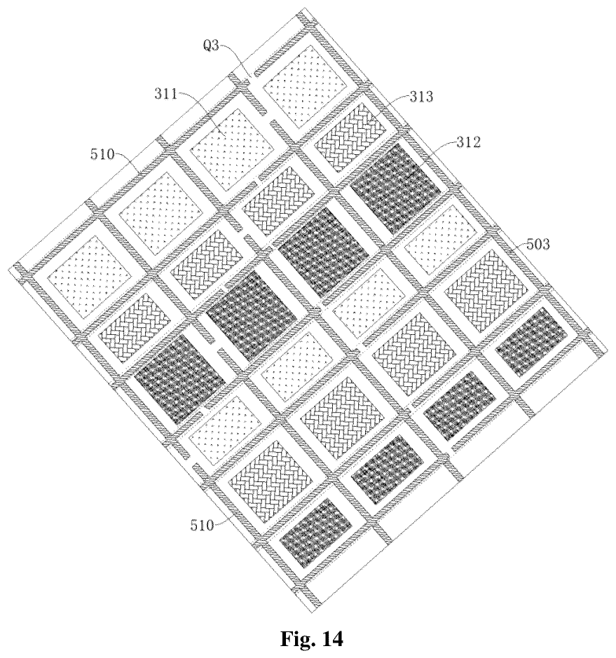

Optionally, as shown in FIG. 14, the touch control layer 500 further includes a dummy electrode 503. A third gap Q3 exists between the dummy electrode 503 and the touch electrode 510. An orthographic projection of the third gap Q3 on the baseplate 100 is located outside the orthographic projection of the overlapping portion 410a on the baseplate 100. This allows more touch lines 511 to overlap with the overlapping portion 410a.

In any of the foregoing embodiments, the composition, manufacturing, etc., of the isolation structure 200 are further described in patents PCT/CN 2023/134518, 202310759370.2, 202310740412.8, 202310707209.0, 202311346196.5, 202310909421.5, for reference.

An embodiment of the second aspect of the present application further provides a display device, including the display panel according to any of the embodiments of the first aspect described above. Since the display device provided by the embodiment of the second aspect of the present application includes the display panel according to any of the embodiments of the first aspect, the display device provided by the embodiment of the second aspect of the present application has the beneficial effects of the display panel according to any of the embodiments of the first aspect, which are not repeated herein.

The display device in the embodiments of the present application includes, but is not limited to, mobile phones, personal digital assistants (PDAs), tablet computers, e-books, televisions, access control systems, smart fixed-line telephones, consoles, and other devices with display functions.

As described in the foregoing embodiments of the present application, these embodiments do not exhaustively describe all details, nor do they limit the present application to only the specific embodiments. Obviously, many modifications and variations are possible based on the above description. This specification selects and specifically describes these embodiments to better explain the principles and practical applications of the present application, so that those skilled in the art can make good use of the present application and modifications based thereon. The present application is limited only by the claims and their full scope and equivalents.

What is claimed is:

1. A display panel, comprising:
a baseplate;
an isolation structure disposed on a side of the baseplate, the isolation structure enclosing an isolation opening;
a light-emitting layer comprising a light-emitting unit located in the isolation opening;
an encapsulation layer comprising a plurality of encapsulation portions located on a side of the light-emitting unit away from the baseplate, the encapsulation portions respectively covering light-emitting units;
a touch control layer located on a side of the encapsulation layer away from the baseplate, the touch control layer comprising a touch electrode, the touch electrode being located on the side of the encapsulation layer away from the baseplate, the touch electrode comprising a touch line,
wherein an orthographic projection of the encapsulation portion on the baseplate and an orthographic projection of the touch line on the baseplate at least partially overlap.

2. The display panel according to claim 1, wherein encapsulation portions corresponding to at least two adjacent light-emitting units overlap with each other to form an overlapping portion, and an orthographic projection of the overlapping portion on the baseplate and the orthographic projection of the touch line on the baseplate at least partially overlap.

3. The display panel according to claim 2, wherein the orthographic projection of the overlapping portion on the baseplate is located within the orthographic projection of the touch line on the baseplate, a width of the overlapping portion is 2 μm to 5 μm; a width of the touch line is 3 μm to 6 μm;
or, the touch line comprises a first touch segment, and an orthographic projection of the first touch segment on the baseplate is located within the orthographic projection of the overlapping portion on the baseplate.

4. The display panel according to claim 2, wherein the encapsulation portion extends from the isolation opening to a side of the isolation structure away from the baseplate, the overlapping portion is located on the side of the isolation structure away from the baseplate, and the orthographic projection of the touch line on the baseplate and an orthographic projection of the isolation structure on the baseplate at least partially overlap.

5. The display panel according to claim 4, wherein in adjacent two encapsulation portions, one comprises a first segment located on the side of the isolation structure away from the baseplate, and the other comprises a second segment located on the side of the isolation structure away from the baseplate,
wherein the first segment comprises a first main body portion, the second segment comprises a second main body portion, a first sidewall, and a third main body portion, the second main body portion is connected to the third main body portion through the first sidewall, the third main body portion is located on a side of the first main body portion away from the baseplate, the third main body portion and the first main body portion overlap to form the overlapping portion, the overlapping portion comprises a part of the first main body portion overlapping with the third main body portion and a part of the third main body portion overlapping with the first main body portion,
an orthographic projection of a side edge of the third main body portion away from the first sidewall on the baseplate is located within the orthographic projection of the touch line on the baseplate.

6. The display panel according to claim 5, wherein an orthographic projection of the third main body portion on the baseplate is located within the orthographic projection of the touch line on the baseplate;
or, an orthographic projection of the first sidewall on the baseplate is located within the orthographic projection of the touch line on the baseplate;
or, an orthographic projection of a side edge of the first main body portion facing the second main body portion on the baseplate is located within the orthographic projection of the touch line on the baseplate.

7. The display panel according to claim 5, wherein a fourth gap exists between the first main body portion and the third main body portion, the fourth gap is provided with an organic filling portion, and a thickness of the organic filling portion is less than a thickness of the first main body portion or the third main body portion.

8. The display panel according to claim 1, wherein encapsulation portions corresponding to at least two adjacent light-emitting units overlap with each other to form an overlapping portion, and in adjacent two encapsulation portions, one comprises a first segment located on a side of the isolation structure away from the baseplate, the other comprises a second segment located on the side of the isolation structure away from the baseplate, the first segment comprises a first main body portion, the second segment comprises a second main body portion, a first sidewall, and a third main body portion, the second main body portion is connected to the third main body portion through the first sidewall, the third main body portion is located on a side of the first main body portion away from the baseplate, the third main body portion and the first main body portion overlap to form the overlapping portion, a first gap is formed between the first main body portion and the first sidewall, and an orthographic projection of the first gap on the baseplate and the orthographic projection of the touch line on the baseplate at least partially overlap.

9. The display panel according to claim 8, wherein the orthographic projection of the first gap on the baseplate is located within the orthographic projection of the touch line on the baseplate.

10. The display panel according to claim 2, wherein a plurality of light-emitting units are arranged in rows and columns along a first direction and a second direction, the first direction being a column direction, the second direction being a row direction;
adjacent two encapsulation portions in a same row along the second direction overlap with each other to form the overlapping portion;
orthographic projections of adjacent two encapsulation portions in a same column along the first direction on the baseplate are spaced apart from each other.

11. The display panel according to claim 10, wherein the plurality of light-emitting units comprise a first light-emitting unit and a second light-emitting unit, a plurality of first light-emitting units are arranged sequentially along the first direction to form a first pixel column, a plurality of second light-emitting units are arranged sequentially along the first direction to form a second pixel column, the first pixel column and the second pixel column are arranged along the second direction,
the encapsulation portions comprise a first encapsulation portion covering the first light-emitting unit and a second encapsulation portion covering the second light-emitting unit, the first encapsulation portion and the second encapsulation portion adjacent along the second direction overlap with each other to form the overlapping portion;
orthographic projections of adjacent two first encapsulation portions along the first direction on the baseplate are spaced apart from each other, and orthographic projections of adjacent two second encapsulation portions along the first direction on the baseplate are spaced apart from each other.

12. The display panel according to claim 11, wherein the plurality of light-emitting units further comprise a third light-emitting unit, a plurality of third light-emitting units are arranged sequentially along the first direction to form a third pixel column, the first pixel column, the second pixel column, and the third pixel column are alternately arranged along the second direction,
the encapsulation portions further comprise a third encapsulation portion covering the third light-emitting unit, the second encapsulation portion and the third encapsulation portion adjacent along the second direction overlap with each other to form the overlapping portion, or the first encapsulation portion and the third encapsulation portion adjacent along the second direction overlap with each other to form the overlapping portion;
orthographic projections of adjacent two third encapsulation portions along the first direction on the baseplate are spaced apart from each other.

13. The display panel according to claim 10, wherein the plurality of light-emitting units comprise a first light-emitting unit, a second light-emitting unit, and a third light-emitting unit, the plurality of encapsulation portions comprise a first encapsulation portion covering the first light-emitting unit, a second encapsulation portion covering the second light-emitting unit, and a third encapsulation portion covering the third light-emitting unit;
wherein the first light-emitting unit and the second light-emitting unit are alternately arranged along the first direction, orthographic projections of the first encapsulation portion and the second encapsulation portion adjacent along the first direction on the baseplate are spaced apart from each other,
the first light-emitting unit and the third light-emitting unit are alternately arranged along the second direction, the first encapsulation portion and the third encapsulation portion adjacent along the second direction form the overlapping portion, or the second light-emitting unit and the third light-emitting unit are alternately arranged along the second direction, the second encapsulation portion and the third encapsulation portion adjacent along the second direction form the overlapping portion.

14. The display panel according to claim 2, wherein
the plurality of light-emitting units comprise a first light-emitting unit, a second light-emitting unit, and a third light-emitting unit, the third light-emitting unit is located within a virtual quadrilateral, two first light-emitting units and two second light-emitting units are alternately distributed at vertices of the virtual quadrilateral;
the plurality of encapsulation portions comprise a first encapsulation portion covering the first light-emitting unit, a second encapsulation portion covering the second light-emitting unit, and a third encapsulation portion covering the third light-emitting unit,
wherein the first encapsulation portion and the third encapsulation portion adjacent along a diagonal direction of the virtual quadrilateral overlap to form the overlapping portion, or the second encapsulation portion and the third encapsulation portion adjacent along the diagonal direction of the virtual quadrilateral overlap to form the overlapping portion.

15. The display panel according to claim 14, wherein orthographic projections of the first encapsulation portion and the second encapsulation portion on the baseplate are spaced apart;
orthographic projections of adjacent two third encapsulation portions on the baseplate are spaced apart.

16. The display panel according to claim 14, wherein the touch line comprises a first wiring portion, the first wiring portion is correspondingly located between the first light-emitting unit and the third light-emitting unit adjacent to the first light-emitting unit, or the first wiring portion is correspondingly located between the second light-emitting unit and the third light-emitting unit adjacent to the second light-emitting unit,
wherein the orthographic projection of the overlapping portion on the baseplate and an orthographic projection of the first wiring portion on the baseplate at least partially overlap.

17. The display panel according to claim 16, wherein the touch line further comprises a second wiring portion, the second wiring portion is correspondingly located between the second light-emitting unit and the first light-emitting unit adjacent to the second light-emitting unit, and at least one second wiring portion encloses a hollowed region.

18. The display panel according to claim 17, wherein the first light-emitting unit and the second light-emitting unit are alternately arranged along a first direction to form a fourth pixel column, the first light-emitting unit and the second light-emitting unit are alternately arranged along a second direction to form a first pixel row, the second wiring portion is correspondingly located between the first light-emitting unit and the second light-emitting unit adjacent along the first direction or the second direction;
the second wiring portion comprises a first sub-wiring and a second sub-wiring, the first sub-wiring is correspondingly located between the first light-emitting unit and the second light-emitting unit adjacent along the first direction, the second sub-wiring is correspondingly located between the first light-emitting unit and the second light-emitting unit adjacent along the second direction;
the hollowed region comprises a first hollowed portion enclosed by at least one first sub-wiring and a second hollowed portion enclosed by at least one second sub-wiring, and an area of an orthographic projection of the first hollowed portion on the baseplate is smaller than an area of an orthographic projection of the second hollowed portion on the baseplate.

19. The display panel according to claim 2, wherein the touch control layer comprises a first touch layer and a second touch layer, an insulating dielectric layer is disposed between the first touch layer and the second touch layer, the touch electrode comprises a first touch segment located in the first touch layer and a second touch segment located in the second touch layer, the insulating dielectric layer is provided with a dielectric via, the first touch segment is electrically connected to the second touch segment through the dielectric via, and an orthographic projection of the dielectric via on the baseplate and the orthographic projection of the overlapping portion on the baseplate are spaced apart.

20. The display panel according to claim 19, wherein the orthographic projection of at least one dielectric via on the baseplate and the orthographic projection of at least one overlapping portion on the baseplate surround different sides of a same isolation opening;
the isolation structure comprises a first isolation segment and a second isolation segment, the orthographic projection of the overlapping portion on the baseplate is located within an orthographic projection of the first isolation segment on the baseplate, the orthographic projection of the dielectric via on the baseplate is located within an orthographic projection of the second isolation segment on the baseplate, and a width of the first isolation segment is less than a width of the second isolation segment;
at least two adjacent encapsulation portions are spaced apart on a side of the second isolation segment away from the baseplate.

21. The display panel according to claim 2, wherein a ratio of a width of the overlapping portion to a width of the touch line is 1.5 to 0.5.

22. The display panel according to claim 21, wherein the orthographic projection of the overlapping portion on the baseplate is located within the orthographic projection of the touch line on the baseplate, the width of the overlapping portion is 2 μm to 5 μm; the width of the touch line is 3 μm to 6 μm.

23. The display panel according to claim 2, wherein the baseplate comprises a substrate and a transistor, the display panel further comprises:
a first insulating layer located on a side of the transistor away from the baseplate, the first insulating layer being provided with a connection via;
a first electrode layer located on a side of the first insulating layer away from the baseplate, the first electrode layer comprising a plurality of first electrodes, a first electrode being electrically connected to the transistor through the connection via,
wherein an orthographic projection of the connection via on the baseplate and the orthographic projection of the overlapping portion on the baseplate are spaced apart.

24. The display panel according to claim 23, wherein the orthographic projection of the connection via on the baseplate and the orthographic projection of the encapsulation portion on the baseplate are spaced apart.

25. The display panel according to claim 2, wherein the touch control layer further comprises a gap, adjacent two touch lines are spaced apart by the gap, and an orthographic projection of at least one gap on the baseplate is located outside the orthographic projection of the overlapping portion on the baseplate.

26. The display panel according to claim 2, wherein
the touch electrode comprises first touch electrodes extending along a first direction and arranged along a second direction, and second touch electrodes extending along the second direction and arranged along the first direction,
a first touch electrode comprises a first touch portion and a first connection portion, the first connection portion connects adjacent two first touch portions,
a second touch electrode comprises a second touch portion and a second connection portion, the second connection portion connects adjacent two second touch portions,
wherein a second gap exists between the first touch portion and the second touch portion adjacent to the first touch portion, and an orthographic projection of the second gap on the baseplate is located outside the orthographic projection of the overlapping portion on the baseplate.

27. The display panel according to claim 1, wherein at least two adjacent encapsulation portions continuously form a continuous region on a side of the isolation structure away from the baseplate, the continuous region is located on the side of the isolation structure away from the baseplate, the touch line comprises a plurality of second touch segments distributed along an extending direction of the touch line, an orthographic projection of at least one second touch segment on the baseplate is located within an orthographic projection of the continuous region on the baseplate, and the continuous region is formed between encapsulation portions corresponding to at least two adjacent light-emitting units of a same light-emitting color.

28. The display panel according to claim 1, further comprising a second electrode located on a side of the light-emitting unit away from the baseplate, the second electrode being electrically connected to the isolation structure;
the isolation structure comprises a first sub-layer and a second sub-layer stacked in a direction away from the baseplate, and an orthographic projection of the first sub-layer on the baseplate is located within an orthographic projection of the second sub-layer on the baseplate.

29. A display device, comprising the display panel according to claim 1.
